(19) United States
(12) Patent Application Publication
(10) Pub. No.: US 2012/0180864 A1
(43) Pub. Date: Jul. 19, 2012

(54) PASTE FOR FORMING OF AN ELECTRODE OF A SOLAR CELL

(75) Inventors: Kun-ho Hwang, Hwaseong (KR); Yong-jun Jung, Hwaseong (KR); Min-soo Ko, Hwaseong (KR); Mee-hye Jeong, Hwaseong (KR)

(73) Assignees: Dongjin Semichem Co., LTD, Incheon (KR); Dongjin Semichem Co., LTD.

(21) Appl. No.: 13/381,214

(22) PCT Filed: Jul. 16, 2010
(86) PCT No.: PCT/KR10/04647

§ 371 Date: Dec. 28, 2011

(30) Foreign Application Priority Data
Jul. 28, 2009 (KR) 10-2009-0068733
Sep. 17, 2009 (KR) 10-2009-0098937

(51) Int. Cl. H01L 31/0224; H01L 31/18; H01B 1/12

(52) U.S. Cl. 136/256; 252/514; 438/98; 257/E31.124

(57) ABSTRACT

There is provided a paste for the production of a solar cell electrode, which exhibits high electrical conductivity, low contact resistance, high aspect ratio, superior storage stability and excellent adhesive strength. When a solar cell electrode is produced from the paste according to the present invention, it can be cured at a drying temperature without undergoing a separate sintering process, thereby increasing productivity in the manufacture of solar cell electrodes

### FIELD OF THE INVENTION

The present invention relates to a paste for the production of a solar cell electrode, which exhibits high electrical conductivity, low contact resistance, high aspect ratio, superior storage stability and excellent adhesive strength. When a solar cell electrode is produced from the paste according to the present invention, it can be cured at a drying temperature without undergoing a separate sintering procedure, thereby increasing productivity in the manufacture of solar cell electrodes

### BACKGROUND OF THE INVENTION

In the prior arts, in manufacturing electrodes for solar cells, organic substances in the pastes were easily eliminated since sintering procedure was carried out at a high temperature of not less than 350° C. However, in the case that electrode materials of which the sintering temperature is below 350° C. are required, organic substances remain in the pastes and they come to function as electrochemical insulators and inhibit the flow of electrons. In particular, of the field of solar cells, amorphous/crystalline silicon heterojunction solar cells require a low-temperature sintering (250° C. or under) condition to suppress the crystallization of the amorphous layers. Therefore, in the electrodes requiring the low-temperature sintering, the remaining organic substances can cause the deterioration of electrical properties

### SUMMARY OF THE INVENTION

Accordingly, it is an object of the present invention to provide a paste for the production of a solar cell electrode, wherein it exhibits high electrical conductivity, low contact resistance, high aspect ratio, superior storage stability and excellent adhesive strength and when a solar cell electrode is produced therefrom, it can be cured at a drying temperature without undergoing a separate sintering procedure, thereby increasing productivity in the manufacture of the solar cell electrodes, and a method of producing an solar cell electrode using the same.

In order to achieve the above objects, the present invention provides a paste for the production of a solar cell electrode, comprising:

(a) a silver power;

(b) at least one conductive polymer selected from the group consisting of PEDOT-PSS, polythiophene, poly(3-alkylthiophene), polypyrrole, poly((2,5 dialkoxy)-p-phenylene vinylene), poly(p-phenylene vinylene), and poly(p-phenylene);

(c) a cellulose derivative; and

(d) a solvent.

It is another object of the invention to provide a method of producing a solar cell electrode using the paste for the production of solar cell electrode, a solar cell electrode produced by the method, and a solar cell comprising the electrode.

The paste for the production of solar cell electrode according to the present invention has the following effects:

1) High productivity: It does not require a separate sintering process since it can be cured to produce an electrode within a short time at a drying temperature (not higher than 100-250° C.).

2) High conductivity and superior electrical resistivity: Conductive polymers are present in the paste at a drying temperature (not higher than 100-250° C.) and they are electrochemically stable thereby to smoothly induce the flow of electrons.

3) Low contact resistance: It shows low contact resistance and it is suitable especially for amorphous/crystalline heterojunction solar cells.

4) Thermal storage stability: It shows superior compatibility with organic binders and solvents and thus, it is highly thermally stable and shows little change in its physical and chemical status.

5) High aspect ratio: It can achieve a high aspect ratio due to the superior rheology properties of the paste.

### DETAILED DESCRIPTION OF THE INVENTION

The invention will be described in detail.

The paste for the production of solar cell electrode according to the present invention comprises:

(a) a silver power;

(b) at least one conductive polymer selected from the group consisting of PEDOT-PSS, polythiophene, poly(3-alkylthiophene), polypyrrole, poly((2,5 dialkoxy)-p-phenylene vinylene), poly(p-phenylene vinylene), and poly(p-phenylene);

(c) a cellulose derivative; and

(d) a solvent.

Preferably, the electrode paste according to the present invention may comprise (a) 30-95 wt. % of the silver power; (b) 0.1-40 wt. % of at least one conductive polymer selected from the group consisting of PEDOT-PSS, polythiophene, poly(3-alkylthiophene), polypyrrole, poly((2,5 dialkoxy)-p-phenylene vinylene), poly(p-phenylene vinylene), and poly(p-phenylene); (c) 0.1-50 wt. % of the cellulose derivative; and (d) a residual amount of the solvent.

The ‘electrode paste for the production of solar cell electrode’ used in the present invention may include pastes used as materials for forming circuits such as wiring boards in mono or multi layers comprising laminating layer structures. Therefore, they may include not only electrodes used for solar cells but also electrical wirings used in these apparatuses.

Each component will be further described in detail.

(a) Silver Powder

The silver powder of the present invention may have preferably an average particle size of 0.05 to 10 μm. It may be advantageous to use a mixture of metal powders having various particle sizes since the accuracy of printing can be increased and when applied to solar cells, the fill factor (FF) of the solar cells can be largely enhanced.

The silver powder may be included in an amount of 30 to 95 wt. % in the paste. If the silver content is less than 30 wt. %, the viscosity of the paste is so low that it may cause wider printing than the pattern size of mask when printed onto a substrate by print screen printing. If the silver content is more than 95 wt. %, its viscosity is so high that it may be difficult to achieve an even dispersion of the conductive powder and it may be difficult for the paste to fall out of the mask during printing, thereby causing a problem in the electrode production and after printing, the substrate may have a poor surface illumination.

(b) Conductive Polymer

The conductive polymer used in the present invention may be selected from the group consisting of PEDOT-PSS, polythiophene, poly(3-alkylthiophene), polypyrrole, poly((2,5 dialkoxy)-p-phenylene vinylene), poly(p-phenylene vinylene), poly(p-phenylene), and a mixture thereof. Further, those obtained by mixing the conductive polymers with a solvent may be used. In particular, the conductive powders selected from the group consisting of PEDOT-PSS, polythiophene, poly(3-alkylthiophene), polypyrrole, poly((2,5 dialkoxy)-p-phenylene vinylene), poly(p-phenylene vinylene), poly(p-phenylene), and a mixture thereof used in the invention show remarkable differences with regard to electrical resistivity, substrate adhesion, contact resistance, aspect ratio and viscosity change rate, when compared to general conductive polymers such as polyaniline.

The conductive polymer may be included in an amount of 0.1 to 40 wt. %. If the amount of the conductive polymer is less than 0.1 wt. %, electrical conductivity is not much improved, and if the amount of the conductive polymer is more than 40 wt. %, the electrode paste to be produced has low viscosity due to low viscosity of the conductive powder, thereby causing the diffusion of the printed pattern linewidths, making it difficult to achieve a high resolution pattern and making it difficult to obtain the electrode pattern of superior aspect ratio.

(c) Cellulose Derivative

The cellulose derivative in the present invention functions as a binder, and it has superior compatibility with the conductive polymers and the solvents and thus remarkably enhances the electrical conductivity and storage stability of the paste for the production of solar cell electrode of the invention. As specific examples of the cellulose derivative of the present invention, there may be used at least one selected from the group consisting of hydroxycellulose, methylcellulose, nitrocellulose, and ethylcellulose.

The cellulose derivative may be included in an amount of 0.1 to 50 wt. %. If the amount of the cellulose derivative is less than 0.1 wt. %, the falling out of the mask can be poor when printing. If the amount is more than 30 wt. %, a large amount of cellulose derivatives can remain after dry is carried out in the regions of 100-250° C. and thus they can decrease substrate adhesion strength by functioning as an element suppressing the curing degree of the electrode paste.

(d) Solvent

The components (a) to (c), when used, may be mixed and dispersed in the solvent.

The applicable solvent may be preferably those having a boiling point of 80-250° C. and for example, there may be used ethylcellosolve acetate, butylcellosolve acetate, propyleneglycol methylether acetate, butylcarbitol acetate, dipropyleneglycol methylether acetate, butylcarbitol, propyleneglycol monomethylether, dipropyleneglycol monomethylether, propyleneglycol monomethylether propionate, ethylether propionate, terpineol, texanol, ethyleneglycol, propyleneglycol, diethyleneglycol, dipropyleneglycol, ethyleneglycol monomethylether, diethyleneglycol monomethylether, diethyleneglycol monoethylether, triethyleneglycol, triethyleneglycol monomethylether, triethyleneglycol monoethylether, propyleneglycol monobutylether, propyleneglycol methylether, dipropyleneglycol methylether, ethyleneglycol monomethylether, dimethylamino formaldehyde, methylethylketone, gammabutyro lactone, or ethyllactate, alone or in combination. Preferably, there may be used butylcarbitol acetate, ethyleneglycol, or a mixture thereof.

The solvent may be included in a residual amount except the components (a) to (c).

(e) Other Additives

In addition to the above components, the electrode paste in accordance with the present invention may further other additives that may be usually included in pastes, if necessary. For example, the additives may include a thickening agent, stabilizer, dispersion agent, defoamer, or surfactant, and they may be preferably used in an amount of 0.1-5 wt. %.

The paste for the production of solar cell electrode paste of the present invention having the above compositions may be obtained by formulating the essential components and optional components in a desired ratio and evenly dispersing them using a blender or a mill such as a 3-axial roll.

Preferably, the paste of the present invention may have a viscosity of 1 to 300 Pa·S when measured using Brookfield HBT Viscometer and a multi-purpose cup using #14 spindle at 10 rpm and 25° C.

The paste for the production of solar cell electrode in accordance with the present invention enables the production of electrodes only by drying process, without requiring a separate sintering process. Accordingly, since the sintering process is not separately required, overall operation is easy, and the conductive polymers that remain inside the paste due to a low temperature drying are electrochemically stable and thus smoothly induce the flow of electrons. These effects may be more increased especially when applied to amorphous/crystalline silicon heterojunction solar cells.

Also, the invention provides a method of producing an electrode for solar cells characterized by printing the above electrode paste onto a substrate and drying it, and a solar cell electrode produced by the method, and a solar cell comprising the solar cell electrode.

In the method of producing solar cell electrode in accordance with the present invention, it is noted that substrates, printing, and drying that have been conventionally used for the production of solar cells can be used except for the use of the above paste for the production of solar cell electrode. For example, the substrates may be a Si substrate; the electrodes may be a front electrode for silicon solar cells; the printing may be screen printing; the drying can be carried out at 100-250° C. for 10 min. to 30 min; and the printing may be optionally controlled and preferably conducted in a thickness of 20 to 50 μm.

As the method of producing solar cell electrode of the present invention does not require a separate sintering process, it has superior operation efficiency and productivity and high accuracy. The solar cells comprising the electrodes produced using the electrode pastes in accordance with the present invention have high efficiency and high resolution and they are suitable particularly for a low-temperature sintering, thereby enabling excellent mass production, and their effects can be more increased when applied to amorphous/crystalline silicon heterojunction solar cells.

For a better understanding of the present invention, preferred examples follow. The following examples are intended to merely illustrate the invention without limiting the scope of the invention.

### EXAMPLES

### Examples 1 to 4 and Comparative Examples 1 and 2

The electrode pastes were prepared by formulating the components in amounts (wt. %) set forth in Table 1 below and then, mixing and dispersing them using a 3-roll mill.

TABLE 1

| | | Electrode Paste (part by weight) | | | | | | |
|---|---|---|---|---|---|---|---|---|
| | | | | | | Com. | | |
| | | Ex. 1 | Ex. 2 | Ex. 3 | Ex. 4 | Ex. 1 | Com. Ex. 2 | Com. Ex. 3 |
| Conductive | Silver | 10 | 30 | 15 | 45 | 10 | | 20 |
| Powder | Powder | | | | | | | |
| | Silver | 30 | 30 | 65 | 45 | 30 | 80 | 65 |
| | Powder | | | | | | | |
| Conductive | PEDOT-PSS | 30 | — | 10 | 4 | — | — | — |
| Polymer | Polypyrrole | — | 10 | — | 3 | — | — | — |
| | Poly(p- | — | 10 | — | — | — | — | — |
| | phenylene | | | | | | | |
| | vinylene) | | | | | | | |
| | Polyaniline | — | — | — | — | — | — | 7 |
| Cellulose | Hydroxy | 4 | 3 | 0.5 | 0.5 | 5 | 1 | 1 |
| Derivative | cellulose | | | | | | | |
| | Ethyl | — | 1.5 | 0.5 | 0.2 | 4 | 2 | 1 |
| | cellulose | | | | | | | |
| Solvent | Butylcarbitol | 12.5 | 7 | 4 | 1 | 25 | 8 | 2 |
| | acetate | | | | | | | |
| | Ethylene | 12.5 | 8 | 4 | 1 | 25 | 8 | 3 |
| | glycol | | | | | | | |
| Additive | Defoamer | 0.5 | 0.5 | 0.5 | — | 0.5 | 0.5 | 0.5 |
| | Dispersion | 0.5 | — | 0.5 | 0.3 | 0.5 | 0.5 | 0.5 |
| | agent | | | | | | | |

Silver powder 1: Spherical silver powder having the particle size of 1.5 μm.
Silver powder 2: Plate-shaped silver powder having the particle size of 2.5 μm
Defoamer: Silicon-type defoamer
Dispersion agent: Alkylol ammonium salt

The electrode pastes produced in Examples 1 to 4 and Comparative Examples 1 and 2 were each measured with regard to their properties (resistivity, substrate adhesion, contact resistance, aspect ratio and viscosity change rate) in accordance with the following methods. The results are shown in Table 2 below.

1) Resistivity (*10⁻⁵Ω·cm)

After the electrode pastes produced in Examples 1 to 4 and Comparative Examples 1 and 2 were printed onto substrates and then cured for 15 min. at 180° C., for 15 min. at 200° C., and for 15 min. at 220° C., their resistivities were measured using a 4-point probe.

2) Substrate Adhesion

In accordance with grid adhesion test (ASTM D3359), 100 grid patterns were added to the pastes that were printed and cured on the substrate, using a crosscut knife. Then, a tape specialized in metal adhesion (3M, #610) was attached thereto and then peeled off, and then the number of the peeled-off grids was counted.

3) Contact Resistance (m Ω·cm)

The electrode pastes produced in Examples 1 to 4 and Comparative Examples 1 and 2 were printed onto the back side of solar cells by a screen printing method and dried using a hot air-type dry oven. Then, the electrode pattern of linewidth of 110 μm was printed onto the front side and dried for 5 min at 160° C. The thus prepared cells were sintered for 15 min. at 220° C. using a sintering furnace. The thus prepared cells were measured using Correscan with regard to their contact resistance.

4) Aspect Ratio (%)

After electrode pattern of linewidth of 110 μm were printed, dried and sintered, the height of the electrode pattern and the pattern linewidth were each measured with SEM and the ratio of the pattern height/pattern linewidth was calculated to see aspect ratio (%).

5) Viscosity Change Rate (%)

After the electrode pastes produced in Examples 1 to 4 and Comparative Examples 1 and 2 were stored at 25° C. for one month, their viscosity change was measured using Brookfield HBT Viscometer at #51 spindle with the condition of shear rate of 3.84 sec-1 under the temperature of 25° C. to observe viscosity change rate.

TABLE 2

| | | | | | | Com. | Com. | Com. |
|---|---|---|---|---|---|---|---|---|
| | | Ex. 1 | Ex. 2 | Ex. 3 | Ex. 4 | Ex. 1 | Ex. 2 | Ex. 3 |
| Resistivity | Curing at | 4.94 | 6.96 | 2.39 | 1.70 | 32.50 | 7.16 | 7.30 |
| (*10⁻⁵ | 180° C. | | | | | | | |
| Ω · cm) | for | | | | | | | |
| | 15 min. | | | | | | | |
| | Curing at | 3.61 | 2.35 | 1.99 | 1.19 | 27.50 | 5.86 | 6.02 |
| | 200° C. | | | | | | | |
| | for | | | | | | | |
| | 15 min. | | | | | | | |
| | Curing at | 1.13 | 1.57 | 1.01 | 0.84 | 8.79 | 3.24 | 4.55 |
| | 220° C. | | | | | | | |
| | for | | | | | | | |
| | 15 min. | | | | | | | |
| Substrate | Tape | 0 | 0 | 0 | 0 | 5 | 10 | 5 |
| Adhesion | Adhesion | | | | | | | |
| | (ASTM | | | | | | | |
| | D3359) | | | | | | | |
| Contact | Solar cell | 7 | 7 | 6 | 6 | 9 | 9 | 9 |
| Resistance | evaluation | | | | | | | |
| (m Ω · | | | | | | | | |
| cm) | | | | | | | | |
| Aspect | Pattern | 21.2 | 24.7 | 25 | 24 | 13.8 | 15.5 | 14.3 |
| Ration | height/ | | | | | | | |
| (%) | pattern | | | | | | | |
| | line width | | | | | | | |
| | ratio after | | | | | | | |
| | sintering | | | | | | | |
| Viscosity | After | 2.5 | 4.7 | 3.2 | 3.1 | 6.9 | 9.3 | 5 |
| Change | storage | | | | | | | |
| Rate | at 25° C. | | | | | | | |
| (%) | for | | | | | | | |
| | 1 month | | | | | | | |

As shown in Table 2, the electrode pastes comprising at least one conductive polymer selected from the group consisting of PEDOT-PSS, polythiophene, poly(3-alkylthiophene), polypyrrole, poly((2,5 dialkoxy)-p-phenylene vinylene), poly(p-phenylene vinylene), and poly(p-phenylene) according to the present invention of Examples 1 to 4 exhibited remarkably enhanced effects in aspects of electrical resistivity, substrate adhesion, contact resistance, aspect ratio and viscosity change rate, in comparison with the electrode pastes of Comparative Examples 1 and 2 comprising no conductive polymers and the electrode paste comprising polyaniline. In particular, the electrode pastes of Examples 1 to 4 according to the present invention remarkably improved resistivity when sintered at low temperatures.

The paste for production of solar cell electrode according to the present invention has the following effects:

1) High productivity: It does not require a separate sintering process since it can be cured to produce an electrode within a short time at a drying temperature (not higher than 100-250° C.).

2) High conductivity and superior electrical resistivity: Conductive polymers are present in the paste at a drying temperature (not higher than 100-250° C.) and they are electrochemically stable thereby to smoothly induce the flow of electrons.

3) Low contact resistance: It shows low contact resistance and it is suitable especially for amorphous/crystalline heterojunction solar cells.

4) Thermal storage stability: It shows superior compatibility with organic binders and solvents and thus, it is highly thermally stable and shows little change in its physical and chemical status.

5) High aspect ratio: It can achieve a high aspect ratio due to the superior rheology properties of the paste.

1. A paste for the production of solar cell electrode, comprising:
(a) a silver power;
(b) at least one conductive polymer selected from the group consisting of PEDOT-PSS, polythiophene, poly(3-alkylthiophene), polypyrrole, poly((2,5 dialkoxy)-p-phenylene vinylene, poly(p-phenylene vinylene), and poly(p-phenylene);
(c) a cellulose derivative; and
(d) a solvent.

2. The paste for the production of solar cell electrode of claim 1, comprising:
(a) 30-95 wt. % of the silver power;
(b) 0.1-40 wt. % of the conductive polymer;
(c) 0.1-50 wt. % of the cellulose derivative; and
(d) a residual amount of the solvent.

3. The paste for the production of solar cell electrode of claim 1, wherein the conductive polymer is at least one selected from the group consisting of PEDOT-PSS, polythiophene, poly(3-alkylthiophene), polypyrrole, poly((2,5 dialkoxy)-p-phenylene vinylene, poly(p-phenylene vinylene), and poly(p-phenylene)

4. The paste for the production of solar cell electrode of claim 1, wherein the cellulose derivative is at least one selected from the group consisting of hydroxycellulose, methylcellulose, nitrocellulose, and ethylcellulose.

5. The paste for the production of solar cell electrode of claim 1, wherein the solvent has a boiling point of 80-250° C.

6. The paste for the production of solar cell electrode of claim 1, wherein the solar cell is an amorphous/crystalline silicon heterojunction solar cell.

7. A method of producing a solar cell electrode, wherein it comprises printing the paste set forth in claim 1 onto a substrate and drying it.

8. A solar cell electrode produced by the method of claim 7.

9. The solar cell electrode of claim 8, wherein the solar cell is an amorphous/crystalline silicon heterojunction solar cell.

10. A solar cell comprising the solar cell electrode set forth in claim 8.
